(19) United States
(12) Patent Application Publication
(10) Pub. No.: US 2016/0276539 A1
(43) Pub. Date: Sep. 22, 2016

(54) SEMICONDUCTOR LIGHT-EMITTING ELEMENT

(71) Applicant: KABUSHIKI KAISHA TOSHIBA, Tokyo (JP)

(72) Inventors: Koji KAGA, Komatsu Ishikawa (JP); Hiroshi KATSUNO, Komatsu Ishikawa (JP); Masakazu SAWANO, Nonoichi Ishikawa (JP); Akira ISHIGURO, Kanazawa Ishikawa (JP); Kazuyuki MIYABE, Kanazawa Ishikawa (JP); Takashi KUNIHIRO, Nomi Ishikawa (JP)

(21) Appl. No.: 15/042,904

(22) Filed: Feb. 12, 2016

(30) Foreign Application Priority Data
Mar. 16, 2015 (JP) 2015-052119

(51) Int. Cl. H01L 33/38; H01L 33/40; H01L 33/44

(52) U.S. Cl. CPC H01L 33/38; H01L 33/44; H01L 33/405

(57) ABSTRACT

A semiconductor light-emitting element includes a first layer having a first conductivity. A second layer having a second conductivity is provided between the first layer and a substrate. A third layer is between the first and second layers. A first electrode is between the substrate and the first layer and is connected to the first layer. An insulating layer is between the first electrode and the substrate and between the first electrode and the second layer. A metal film is between the insulating layer and the substrate and covers the insulating layer and the second layer. The first electrode is in a concave portion extending between the second layer and the first layer. The insulating layer has a surface having a region in which a distance between the insulating layer and the substrate is decreased in a direction from the second layer to the first electrode.

### CROSS-REFERENCE TO RELATED APPLICATION

This application is based upon and claims the benefit of priority from Japanese Patent Application No. 2015-052119, filed Mar. 16, 2015, the entire contents of which are incorporated herein by reference.

### FIELD

Embodiments described herein relate generally to a semiconductor light-emitting element.

### BACKGROUND

There is a demand for improvement of stable characteristics in a semiconductor light-emitting element such as light-emitting diode (LED).

### DESCRIPTION OF THE DRAWINGS

FIGS. 1A to 1C are schematic views which illustrate a semiconductor light-emitting element according to a first embodiment.

FIGS. 2A to 2F are schematic cross sectional views depicting a method of manufacturing the semiconductor light-emitting element according to the first embodiment.

FIG. 3 is a schematic sectional view which illustrates a portion of the semiconductor light-emitting element according to the first embodiment.

FIG. 4 is a schematic sectional view which illustrates a portion of a semiconductor light-emitting element according to a second embodiment.

FIG. 5 is a schematic sectional view which illustrates a portion of a semiconductor light-emitting element according to a third embodiment.

### DETAILED DESCRIPTION

Embodiments described herein provide a semiconductor light-emitting element with stable device characteristics.

In general, according to one embodiment, a semiconductor light-emitting element includes a substrate, a first semiconductor layer of a first conductivity type on the substrate, a second semiconductor layer of a second conductivity type, a third semiconductor layer, a first electrode, an insulating layer, and a metal film. The first semiconductor layer is spaced from the substrate in a first direction. The second semiconductor layer is between the first semiconductor layer and the substrate. The third semiconductor layer is between the first semiconductor layer and the second semiconductor layer. The first electrode is provided between the substrate and the first semiconductor layer and is electrically connected to the first semiconductor layer. The insulating layer is provided between the first electrode and the substrate and between the first electrode and the second semiconductor layer. The metal film is provided between the insulating layer and the substrate, and covers the insulating layer and the second semiconductor layer. The first electrode is provided in a concave portion which extends between the second semiconductor layer and the first semiconductor layer. The insulating layer has a first surface facing the substrate, and the first surface has a region in which a distance between the insulating layer and the substrate is decreased in a direction from the second semiconductor layer to the first electrode.

Hereinafter, each embodiment of the present invention will be described with reference to drawings.

The drawings are schematic or conceptual, and are not necessarily drawn to scale.

In the present disclosure, an element described in and earlier figure is labelled with the same reference numeral, and detailed description thereof may be omitted where such description would be repetitive.

### First Embodiment

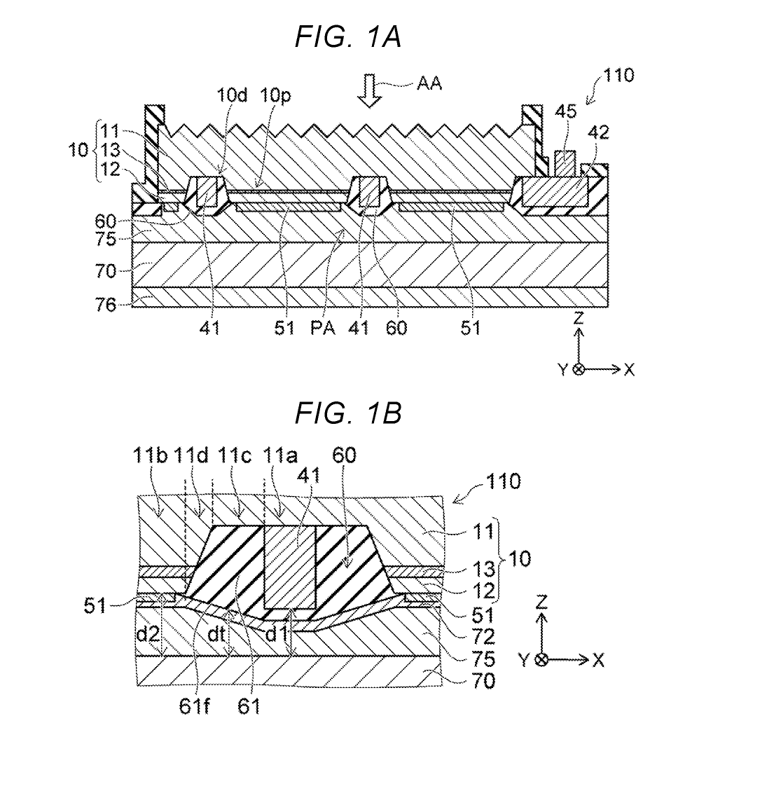

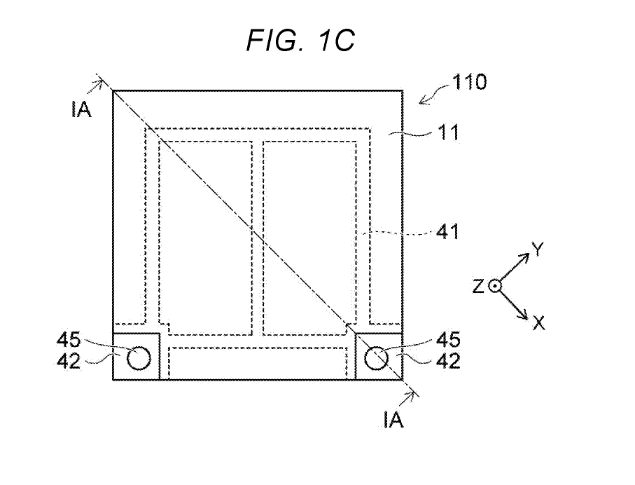

FIGS. 1A to 1C are schematic views which illustrate a semiconductor light-emitting element according to the first embodiment.

FIG. 1A is a sectional view taken along line IA-IA of FIG. 1C. FIG. 1B is a sectional view which shows an enlarged portion PA shown in FIG. 1A. FIG. 1C is a plan view viewed along an arrow AA of FIG. 1A.

As shown in FIG. 1A, a semiconductor light-emitting element 110 includes a first semiconductor layer 11, a second semiconductor layer 12, a third semiconductor layer 13, a substrate 70, an insulating layer 60, a first electrode 41, and a second electrode 51.

The substrate 70 may be a semiconductor material such as silicon (Si) or sapphire, and may be electrically conductive.

The first semiconductor layer 11 is first conductivity type. The first semiconductor layer 11 is separated from the substrate 70 in a first direction. A direction from the substrate 70 to the first semiconductor layer 11 is the first direction.

The first direction may be defined as a Z axis direction. A direction perpendicular to the Z axis direction may be defined as an X axis direction, and may be referred to herein as a second direction. A direction perpendicular to the Z axis direction and the X axis direction is defined as a Y axis direction.

The first semiconductor layer 11 includes a first semiconductor region 11a, a second semiconductor region 11b which is aligned with the first semiconductor region 11a in the second direction, and a third semiconductor region 11c between the first semiconductor region 11a and the second semiconductor region 11b. The first semiconductor layer 11 further includes a fourth semiconductor region 11d between the second semiconductor region 11b and the third semiconductor region 11c.

The second semiconductor layer 12 is a second conductivity type. The second semiconductor layer 12 is provided between the second semiconductor region 11b and the substrate 70. The second semiconductor layer 12 and the first semiconductor layer 11 are stacked in the Z axis direction.

The first conductivity type may be an n-type, and the second conductivity type may be a p-type. Alternately, the first conductivity type may be p-type and the second conductivity type may be n-type. In the following example, the first conductivity type is n-type, and the second conductivity type is p-type.

The third semiconductor layer 13 is between the second semiconductor region 11b and the second semiconductor layer 12. The third semiconductor layer 13 may include an active layer, and may be a light-emitting portion.

The first semiconductor layer 11, the second semiconductor layer 12, and the third semiconductor layer 13 are included in the stacked body 10. The stacked body 10 extends along an X-Y plane, which is the plane orthogonal to the Z axis direction. The stacked body 10 includes a convex portion 10p having a mesa shape. The convex portion 10p includes a portion of the second semiconductor region 11b, the third semiconductor layer 13, and the second semiconductor layer 12. A concave portion 10d which is aligned with the convex portion 10p in the X axis direction is provided in the stacked body 10.

The first semiconductor layer 11, the second semiconductor layer 12, and the third semiconductor layer 13 may include a nitride semiconductor. The first semiconductor layer 11 may include a gallium nitride (GaN) layer containing n-type impurities, which may be silicon (Si), oxygen (O), germanium (Ge), tellurium (Te), and/or tin (Sn). The first semiconductor layer 11 may include an n-side contact layer. The second semiconductor layer 12 may include a GaN layer containing p-type impurities, which may be magnesium (Mg), zinc (Zn), and/or cobalt (C). The second semiconductor layer 12 may include a p-side contact layer.

The first electrode 41 is between the substrate 70 and the first semiconductor region 11a, and is electrically connected to the first semiconductor region 11a. The first electrode 41 may be an n electrode. The first electrode 41 may contain aluminum (Al) or an aluminum alloy, and may be light-reflective.

The second electrode 51 is provided between the substrate 70 and the second semiconductor layer 12, and is electrically connected to the second semiconductor layer 12 and the substrate 70. The second electrode 51 may be a p electrode. The second electrode 51 may contain silver (Ag) or a silver alloy, and may be light-reflective.

In the present disclosure, when two items are described as being electrically connected, it means the two items are either directly connected or connected by a conductor between the two items to carry electrical current between the two items. In this disclosure, when items are described as overlapping, it means the two items overlap when viewed in a projection onto the X-Y plane.

The insulating layer 60 is between the substrate 70 and the first electrode 41, and electrically insulates the first electrode 41 from the substrate 70 and the second electrode 51. The insulating layer 60 includes the first insulating portion 61, which is between the substrate 70 and the third semiconductor region 11c. The first insulating portion 61 extends between the substrate 70 and the first electrode 41, between the substrate 70 and the fourth semiconductor region 11d, and between the substrate 70 and a portion of the second semiconductor layer 12. The insulating layer 60 is between the first electrode 41 and the convex portion 10p along the X axis direction, and covers portions of the first electrode 41 and the second semiconductor layer 12. The insulating layer may contain silicon oxide, silicon nitride, silicon oxynitride.

A metal layer 75 is between the substrate 70 and the second electrode 51, and between the substrate 70 and the insulating layer 60. The metal layer 75 may contain any of tin (Sn), gold (Au), nickel (Ni), an alloy containing tin and gold, and/or an alloy containing tin and nickel. The metal layer 75 is electrically connected to the substrate 70 and the second electrode 51.

Omitted metal film 72 is shown in FIG. 1B, but it omitted from FIG. 1A. The metal film 72 is between the second electrode 51 and the metal layer 75, and between the insulating layer 60 and the metal layer 75. The metal film 72 may be a barrier metal, and is preferably light-reflective. The metal film may contain any of titanium (Ti), platinum (Pt), an alloy containing titanium and platinum, silver, and/or a silver alloy, or any other similar material.

The semiconductor light-emitting element 110 includes a pad 45 and a pad wiring 42. The first electrode 41, the second electrode 51, the insulating layer 60, and the stacked body 10 are disposed on a portion of the metal layer 75. The pad wiring 42 is disposed on another portion of the metal layer 75. The pad 45 is disposed on the pad wiring 42.

As shown in FIG. 1C, the pad wiring 42 is connected to the first electrode 41. The pad 45 is electrically connected to the first semiconductor layer 11 through the pad wiring 42 and the first electrode 41. The substrate 70 is electrically connected to the second electrode 51 through the metal film 72 and the metal layer 75.

When a voltage is applied between the pad 45 and the substrate 70, a current is supplied to the third semiconductor layer 13, and light is emitted from the third semiconductor layer 13. The emitted light is emitted to the outside of the semiconductor light-emitting element 110 through the exposed surface of the first semiconductor layer 11, which is a light emitting surface. Light emitted toward the substrate 70 is reflected by the second electrode 51 and the first electrode 41. The semiconductor light-emitting element 110 may be an LED.

In the embodiment of FIGS. 1A-1C, the first electrode 41 is relatively thick for low electrical resistance and uniform light emission. Thus, high light-emitting efficiency is obtained. For example, a distance dl between the first electrode 41 and the substrate 70 is shorter than a distance d2 between the second semiconductor layer 12 and the substrate 70.

In the embodiment of FIGS. 1A-1C, the first insulating portion 61 of the insulating layer 60 has a first surface 61f (FIG. 1B). The first surface 61f faces the substrate 70 and is inclined with respect to the substrate 70. A distance dt between the first insulating portion 61 and the substrate 70 in the Z axis direction declines in a direction from the second semiconductor layer 12 to the first electrode 41. The distance dt may decline monotonically and/or continuously.

Hereinafter, a method of manufacturing the semiconductor light-emitting element 110 will be described.

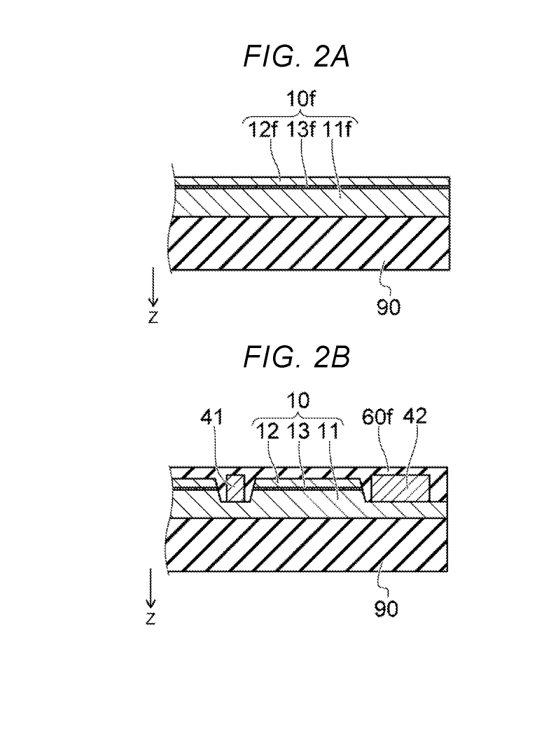

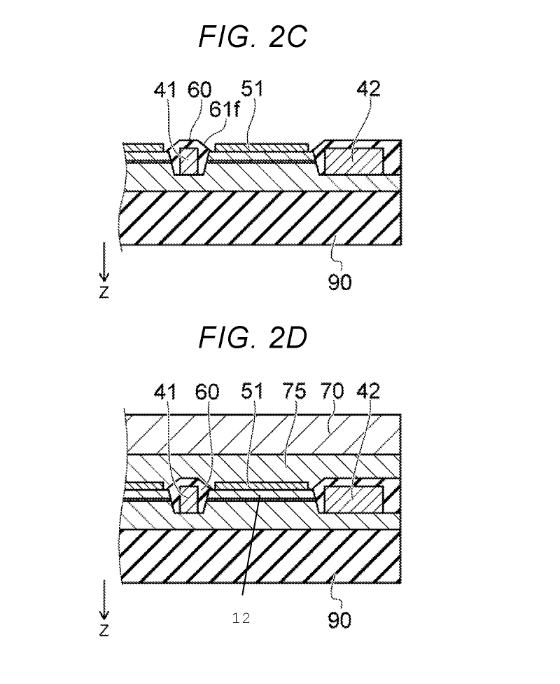

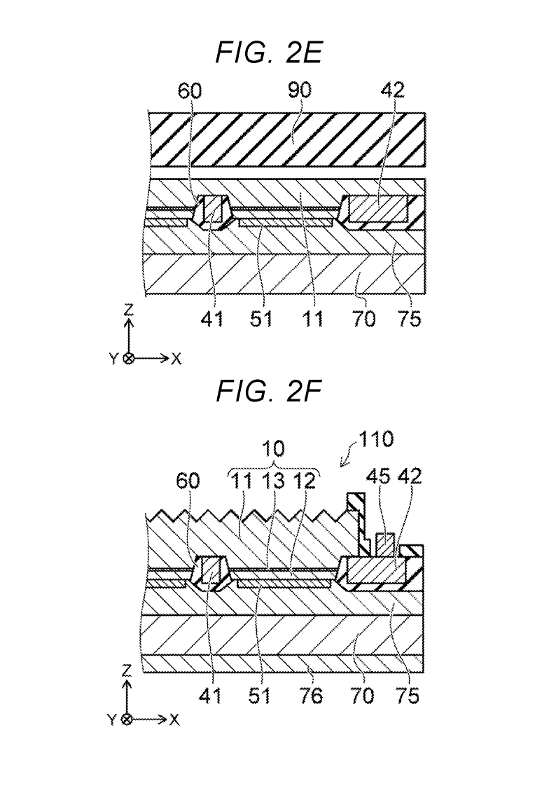

FIGS. 2A to 2F are schematic sectional views of a process sequence which illustrate the method of manufacturing the semiconductor light-emitting element 110.

As shown in FIG. 2A, a first semiconductor film 11f, corresponding to the first semiconductor layer 11, is formed on a growth substrate 90. A buffer layer (not shown) may be formed between the first semiconductor film. 11f and the growth substrate 90. A third semiconductor film 13f, corresponding to the third semiconductor layer 13, is formed on the first semiconductor film 11f. A second semiconductor film 12f, corresponding to the second semiconductor layer 12, is formed on the third semiconductor film 13f. Accordingly, a stacked film 10f, corresponding to the stacked body 10, is obtained. Metal organic chemical vapor deposition (MOCVD) and the like may be used to form the films 11f, 12f, and 13f. The growth substrate may contain Si, SiO₂, AlO₂, quartz, sapphire, GaN, SiC, and/or GaAs.

As shown in FIG. 2B, the stacked body 10 is formed by removing a portion of the second semiconductor film 12f, a portion of the third semiconductor film 13f, and a portion of the first semiconductor film 11f. Reactive ion etching (RIE) and the like may be used in the removal process. The result is a mesa shape, including the convex portion 10p and the concave portion 10d, formed in the stacked body 10.

The first electrode 41 and the pad wiring 42 are formed on the first semiconductor layer 11 of the stacked body 10. Furthermore, an insulating film 60f which is a portion of the insulating layer 60 is formed on the stacked body 10 and on the first electrode 41. Chemical vapor deposition (CVD), sputtering, and/or spin on glass (SOG) methods, or the like may be used.

As shown in FIG. 2C, the insulating layer 60 is formed by removing a portion of the insulating film 60f. Removal of the portion of the insulating film 60f exposes at least a portion of the stacked body 10. The surface 61f of the insulating layer 60 is inclined with respect to the Z axis direction. Inclining (shaping) of the surface 61f may be accomplished by the removal process.

As shown in FIG. 2D, the second electrode 51 is formed on the second semiconductor layer 12, and the optional metal film 72, for example, a stacked film of Ti/Pt/Ti, (not shown in FIG. 2D) and a metal film which is a portion of the metal layer 75 are formed on the second electrode 51 and the insulating layer 60. A structure which includes the substrate 70, and a metal film which is another portion of the metal layer 75 disposed on the substrate 70 is separately prepared. The metal film disposed on the substrate 70 is bonded to the metal film formed on the second electrode 51 and the insulating layer 60 to form the metal layer 75.

As shown in FIG. 2E, the growth substrate 90 is removed by grinding, dry etching (for example, RIE), laser lift off (LLO), or the like.

As shown in FIG. 2F, a portion of the stacked body 10 is removed to expose the pad wiring 42, and the pad 45 is formed on the pad wiring 42. Unevenness (roughness) may be formed on an upper surface of the first semiconductor layer 11 for limiting interfacial reflections. A protective film, which may be an insulating layer, may be formed on a side surface of the stacked body 10. The substrate 70 may be thinned to any desired extent. In the manufacture process described above, sequences of processing may be changed in a technically allowed range. Annealing processing may be appropriately performed at one or more points in the processing.

Accordingly, the semiconductor light-emitting element 110 is obtained.

Inclining of the surface 61f with respect to the substrate 70 provides advantages that lead to stable operation of the semiconductor light-emitting element 110.

For example, if the first surface 61f is parallel to the substrate 70, a side surface of the first insulating portion 61 is at a right angle with respect to a bottom surface of the first insulating portion 61. With such a structure, the first insulating portion 61 is easily damaged (cracks, and the like) near the end of the first insulating portion 61, resulting in deterioration in performance of the insulating layer 60 and reliability of the semiconductor light-emitting element. The metal film 72 or the metal layer 75 may also peel because bonding of the right-angle portion of the first insulating portion 60 to the metal layer 75 would not be stable, resulting in lower yield.

In contrast, in the semiconductor light-emitting element 110, the first surface 61f (FIG. 1B) of the insulating layer 60 is inclined with respect to the substrate 70. The first surface 61f extends substantially along the second semiconductor layer 12 at the end of the first insulating portion 61 reducing occurrence of damage (cracks, and the like) to the first insulating portion 61 in the vicinity of the end of the first insulating portion 61. Accordingly, a high insulation property is obtained in the insulating layer 60 and stable characteristics maybe obtained. Furthermore, peeling of the metal film 72 and/or the metal layer 75 is suppressed and stable bonding is obtained.

In this manner, according to the embodiment, it is possible to provide a semiconductor light-emitting element which may obtain stable characteristics.

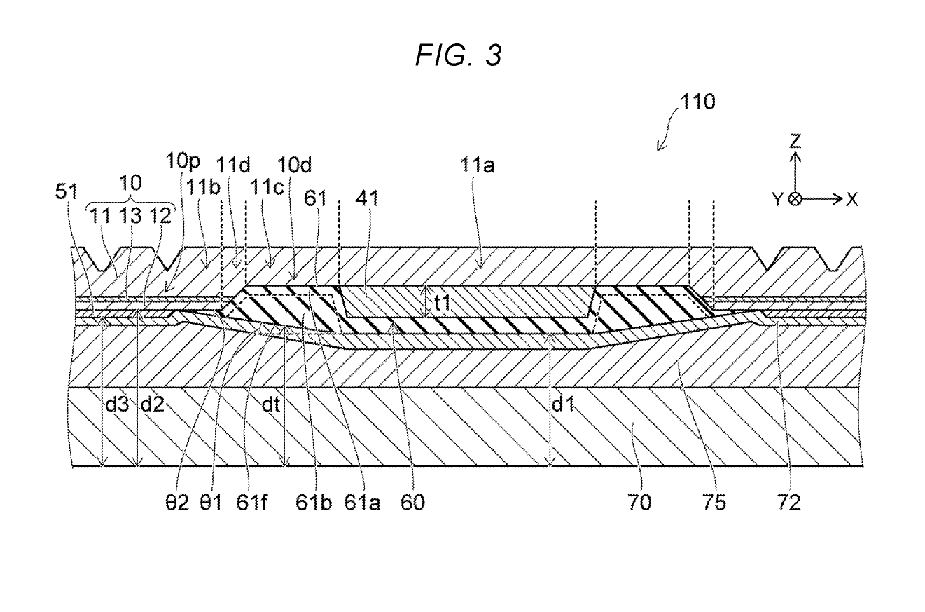

FIG. 3 is a schematic sectional view which illustrates a portion of the semiconductor light-emitting element 110 according to the first embodiment.

FIG. 3 illustrates an enlarged portion of FIG. 1A. In the embodiment of FIG. 3, an absolute value of an angle θ1 between a plane of the first surface 61f and the substrate 70 is greater than 0 degrees and not more than 10 degrees. When the angle θ1 is 0 degrees, an upper end of an electrode cannot be completely protected in some cases. When the angle θ1 is greater than 10 degrees, for example, cracks are generated in some cases. A range of the angle θ1 includes a case where the first electrode 41 is formed to be relatively thin, and a mesa step is deeply etched. Based on the substrate 70, an angle of being inclined to a side of the first electrode 41 is set as “+” (positive), and an angle of being inclined to a side opposite to the side of the first electrode 41 is set as “−” (negative) .

An angle θ2 between a plane having the first surface 61f and a portion of the second semiconductor layer 12 is from 1 degree to 10 degrees. When the angle θ2 is less than one degree, for example, the upper end of an electrode cannot be completely protected in some cases. When the angle θ2 is greater than 10 degrees, for example, cracks may occur in some cases.

A thickness t1 of the first electrode 41 is from 0.6 micrometer (μm) to 2.0 μm. When the thickness t1 is less than 0.6 μm, for example, current capacity is insufficient and fusion occurs in some cases. When the thickness t1 is greater than 2.0 μm, for example, the first electrode cannot be covered with a protective film, and electrical short circuits are caused in some cases.

A distance d1 between the first electrode 41 and the substrate 70 in the Z axis direction is 1.0 to 1.5 times a distance d3 between the second electrode 51 and the substrate 70 in the Z axis direction. When the distance d1 is shorter than 1.0 times the distance d3, for example, a large void may be generated right under the first electrode 41. When the distance dl is longer than 1.5 times the distance d3, for example, a large void may be generated on both side surfaces of the first electrode 41.

As shown in FIG. 3, in the example, the insulating layer 60 includes a first film 61a and a second film 61b. The first film 61a overlaps the first semiconductor region 11a, the third semiconductor region 11c, and the fourth semiconductor region 11d The second film 61b is provided between a portion of the first film 61a and the substrate 70, for example between a portion of the first film 61a and the metal film 72. The second film 61b overlaps the third semiconductor region 11c. That is, the first insulating portion 61 includes the first film 61a and the second film 61b. In the first insulating portion 61, the first film 61a is provided between the second film 61b and the third semiconductor region 11c. The first film 61a is in contact with the third semiconductor region 11c, and may contain silicon oxide. The first film 61a may be formed by plasma chemical vapor deposition (CVD). The second film 61b may contain silicon oxide and may be formed by a spin on glass (SOG) method.

The first film 61a is provided in a step portion of the stacked body 10. The first film 61a has a shape that conforms to the step portion. The step portion is filled with the second film 61b. Accordingly, the first surface 61f of the first insulating portion 61 has a gentle slope -shape, covering of the metal film 72 is improved, and bonding by the metal layer 75 is reliably performed.

Forming the second film 61b is not limited to the SOG method. For example, the insulating layer may have a thickness 1.5 times or more a height of the step portion using, for example, a plasma CVD method and applying photoresist thereto to perform etch-back processing by dry etching or wet etching. Alternately, planarization using chemical mechanical polishing (CMP) may be used.

In the embodiment of FIG. 3, a light reflectance of the first electrode 41 may be higher than a light reflectance of the metal layer 75. A light reflectance of the second electrode 51 may also be higher than a light reflectance of the metal layer 75. The light reflectance described above may be the light reflectance at a peak wavelength, the wavelength at which light intensity is maximum, of light emitted from the third semiconductor layer 13. As a result, high light extraction efficiency is obtained.

### Second Embodiment

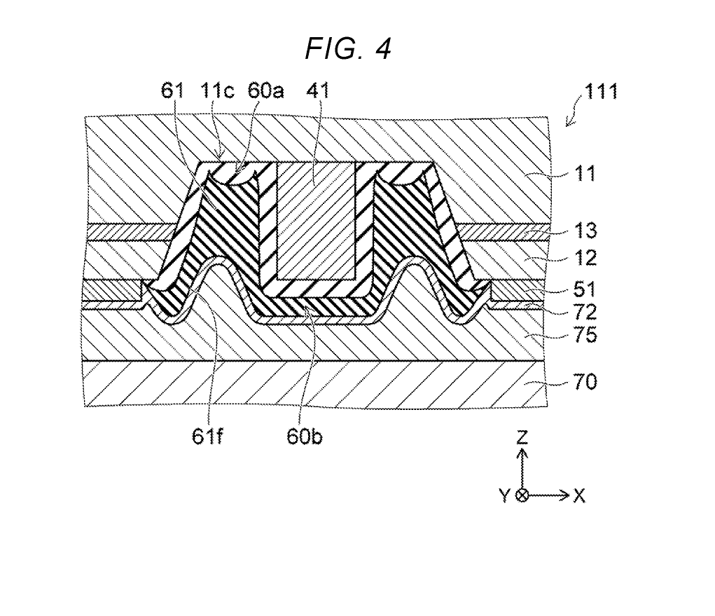

FIG. 4 is a schematic sectional view which illustrates a portion of a semiconductor light-emitting element 111 according to a second embodiment.

FIG. 4 shows a portion corresponding to one portion PA shown in FIG. 1A.

A semiconductor light-emitting element 111 includes a first insulating layer 60a and a second insulating layer 60b in addition to the first to the third semiconductor layers 11 to 13, the first electrode 41, the second electrode 51, the substrate 70, the metal layer 75, and the metal film 72. Other than the first insulating layer 60a and the second insulating layer 60b, the semiconductor light-emitting element 111 is the same as the semiconductor light-emitting element 110.

The first insulating layer 60a is between the third semiconductor region 11c and the substrate 70, and between the first electrode 41 and the substrate 70. The second insulating layer 60b is between the first insulating layer 60a and the substrate 70.

Thus, the insulating layer 60 of FIG. 1A may include a plurality of layers, as in the embodiment of FIG. 4. The first insulating layer 60a may contain silicon oxide, and the second insulating layer 60b may contain silicon nitride.

The second insulating layer 60b includes the first insulating portion 61. The first insulating portion 61 is provided between the third semiconductor region 11c and the substrate 70. The first insulating portion 61 has the first surface 61f.

In the embodiment of FIG. 4, the distance between the first insulating portion 61 and the substrate 70 in the first direction (Z axis direction) has a region in which the distance is decreased in a direction from the first electrode 41 to the second semiconductor layer 12. Accordingly, the first surface 61f is curved. The first surface 61f is concave-shaped. The first surface 61f is curved with respect to the substrate 70.

Curvature increases a contact area between the first surface 61f and the metal film 72. An area in which the first surface 61f and the metal layer 75 are in contact is increased. Accordingly, for example, adhesion between the metal film 72 (metal layer 75) and the second insulating layer 60b is increased, and peeling and the like of the metal film 72 may be suppressed. Accordingly, stable characteristics are obtained.

The first insulating layer 60a is in contact with the third semiconductor region 11c, and may contain silicon oxide. In forming the first insulating layer 60a, plasma CVD may be used. The second insulating layer 60b may contain silicon nitride, and may be formed by plasma CVD and etch-back processing. For example, a method of forming the second insulating layer 60b to be thick may include a plasma CVD method, and applying photoresist to perform etch-back processing by dry etching or wet etching.

### Third Embodiment

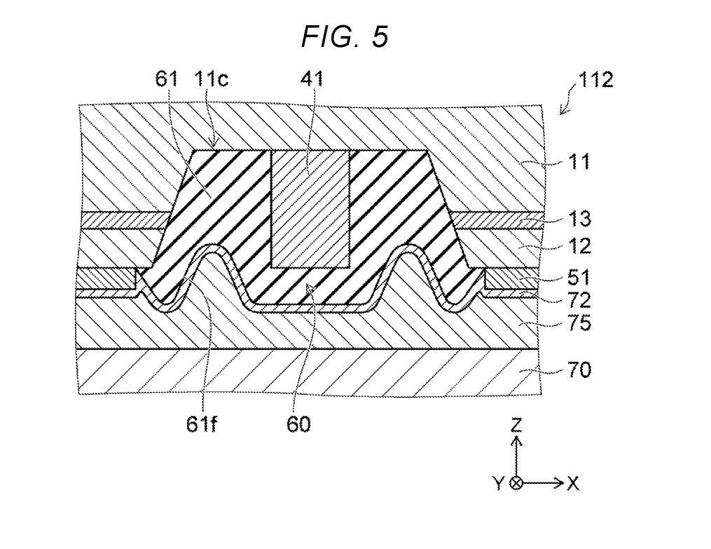

FIG. 5 is a schematic sectional view which illustrates a portion of a semiconductor light-emitting element 112 according to a third embodiment.

FIG. 5 shows a portion corresponding to a portion PA shown in FIG. 1A.

The semiconductor light-emitting element 112 includes the insulating layer 60 in addition to the first to third semiconductor layers 11 to 13, the first electrode 41, the second electrode 51, the substrate 70, the metal layer 75, and the metal film 72. In the semiconductor light-emitting element 112, the insulating layer 60 is configured differently, and other than the configuration of the insulating layer 60, the semiconductor light-emitting element 112 is the same as the semiconductor light-emitting element 110.

The insulating layer 60 in FIG. 5 is provided between the third semiconductor region 11c and the substrate 70, and between the first electrode 41 and the substrate 70.

In this embodiment, the insulating layer 60 is a single layer. The insulating layer 60 may contain silicon oxide.

The insulating layer 60 includes the first insulating portion 61. The first insulating portion 61 is provided between the third semiconductor region 11c and the substrate 70. The first insulating portion 61 has a curved, concave first surface 61f. The first surface 61f is curved with respect to the substrate 70.

According to the embodiment of FIG. 5, the curvature increases contact area between the first surface 61f and the metal film 72, improving adhesion between the metal film 72 (and/or metal layer 75) and the second insulating layer 60b, and reducing peeling and the like of the metal film 72. Accordingly, stable characteristics are obtained.

According to the embodiment, it is possible to provide a semiconductor light-emitting element which may obtain stable characteristics.

As described above, embodiments of the invention are described with reference to the specific examples. However, the present disclosure is not limited to these specific examples.

In addition, elements in different specific examples may be combined when technically feasible.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

What is claimed is:

1. A semiconductor light-emitting element, comprising:
a substrate;
a first semiconductor layer of a first conductivity type on the substrate, the first semiconductor layer being spaced from the substrate in a first direction;
a second semiconductor layer of a second conductivity type between the first semiconductor layer and the substrate;
a third semiconductor layer between the first semiconductor layer and the second semiconductor layer;
a first electrode provided between the substrate and the first semiconductor layer and electrically connected to the first semiconductor layer;
an insulating layer provided between the first electrode and the substrate and between the first electrode and the second semiconductor layer; and
a metal film provided between the insulating layer and the substrate, and covering the insulating layer and the second semiconductor layer,
wherein the first electrode is provided in a concave portion which extends between the second semiconductor layer and the first semiconductor layer, and the insulating layer has a first surface facing the substrate, and the first surface has a region in which a distance between the insulating layer and the substrate is decreased in a direction from the second semiconductor layer to the first electrode.

2. The semiconductor light-emitting element according to claim 1, wherein a distance between the first electrode and the substrate is shorter than a distance between the second semiconductor layer and the substrate.

3. The semiconductor light-emitting element according to claim 1, wherein an absolute value of an angle between a plane of the first surface and a plane of the substrate is greater than 0 degrees and not more than 10 degrees.

4. The semiconductor light-emitting element according to claim 1, wherein the insulating layer extends between a portion of the second semiconductor layer and the substrate.

5. The semiconductor light-emitting element according to claim 3, wherein
the insulating layer extends between a portion of the second semiconductor layer and the substrate, and
an angle between the plane of the first surface and the portion of the second semiconductor layer is within a range from 1 degree to 10 degrees.

6. The semiconductor light-emitting element according to claim 5, wherein the insulating layer extends between the first electrode and the substrate.

7. The semiconductor light-emitting element according to claim 2, wherein a thickness of the first electrode is within a range of 0.6 micrometers to 2.0 micrometers.

8. The semiconductor light-emitting element according to claim 2, further comprising:
a second electrode between the second semiconductor layer and the substrate and electrically connected to the second semiconductor layer,
wherein the distance between the first electrode and the substrate is 1.0 to 1.5 times a distance between the second electrode and the substrate.

9. The semiconductor light-emitting element according to claim 8, further comprising:
a metal layer between the second electrode and the substrate and between the insulating layer and the substrate,
wherein the second electrode is electrically connected to the metal layer.

10. The semiconductor light-emitting element according to claim 1, wherein the first surface further has a region in which the distance between the insulating layer and the substrate is decreased in a direction from the first electrode to the second semiconductor layer.

11. The semiconductor light-emitting element according to claim 10,
wherein the insulating layer has a multi-layered structure including a first insulating layer and a second insulating layer.

12. The semiconductor light-emitting element according to claim 11, wherein
the first insulating layer comprises silicon oxide, and
the second insulating layer comprises silicon nitride.

13. The semiconductor light-emitting element according to claim 11, wherein
the first insulating layer is disposed between the first semiconductor layer and the substrate in the concave portion,
the second insulating layer is disposed between the first insulating layer and the substrate in the concave portion, and
a portion of the first insulating layer extends between a portion of the second semiconductor layer and the substrate.

14. The semiconductor light-emitting element according to claim 13, wherein a portion of the second insulating layer extends between the portion of the second semiconductor layer and the substrate.

15. The semiconductor light-emitting element according to claim 11, further comprising:
a second electrode between the second semiconductor layer and the substrate, the second electrode being electrically connected to the second semiconductor layer.

16. The semiconductor light-emitting element according to claim 15, further comprising:
a metal layer between the second electrode and the substrate, and between the insulating layer and the substrate,
wherein the second electrode is electrically connected to the metal layer.
